(19) United States
(12) Patent Application Publication
(10) Pub. No.: US 2015/0137062 A1
(43) Pub. Date: May 21, 2015

(54) Mimcaps with quantum wells as selector elements for crossbar memory arrays

(71) Applicant: Intermolecular Inc., San Jose, CA (US)

(72) Inventors: Venkat Ananthan, Cupertino, CA (US); Prashant B Phatak, San Jose, CA (US)

(21) Appl. No.: 14/560,031

(22) Filed: Dec. 4, 2014

Related U.S. Application Data
(63) Continuation-in-part of application No. 13/974,278, filed on Aug. 23, 2013, now Pat. No. 8,933,429.
(60) Provisional application No. 61/785,069, filed on Mar. 14, 2013.

(51) Int. Cl. H01L 27/24; H01L 49/02

(52) U.S. Cl. CPC H01L 27/2418; H01L 27/2481; H01L 28/60
USPC 257/4; 257/532

(57) ABSTRACT

Selector devices suitable for memory arrays have low leakage currents at low voltages, reducing sneak current paths for non-selected devices, and high leakage currents at high voltages, reducing voltage drops during switching. The selector device may include a non-conductive tri-layer between two electrodes. The non-conductive tri-layer may include a low-bandgap dielectric layer between two higher-bandgap dielectric layers. The high-bandgap dielectric layers may be doped to form traps at energy levels higher than the write voltage of the memory device. With a thin low-bandgap layer and a large bandgap difference from the high-bandgap layers, the selector may operate as a quantum well, conductive when the electrode Fermi level matches the lowest energy level of the quantum well and insulating at lower voltages.

This application is a continuation-in-part claiming priority to U.S. patent application Ser. No. 13/974,278, filed Aug. 23, 2013, which itself claims priority to U.S. Provisional Patent Application No. 61/785,069 filed on Mar. 14, 2013, each of which is entirely incorporated by reference herein for all purposes.

### FIELD OF THE INVENTION

This invention relates generally to non-volatile memory arrays, and more particularly, to current selectors used in nonvolatile memory arrays.

### BACKGROUND

Nonvolatile memory elements are used in systems in which persistent storage is required. For example, digital cameras use nonvolatile memory cards to store images and digital music players use nonvolatile memory to store audio data. Nonvolatile memory is also used to persistently store data in computer environments. Nonvolatile memory is often formed using electrically-erasable programmable read only memory (EPROM) technology. This type of nonvolatile memory contains floating gate transistors that can be selectively programmed or erased by application of suitable voltages to their terminals.

As fabrication techniques improve, it is becoming possible to fabricate nonvolatile memory elements with increasingly smaller dimensions. However, as device dimensions shrink, scaling issues are posing challenges for traditional nonvolatile memory technology. This has led to the investigation of alternative nonvolatile memory technologies, including resistive memory devices, such as resistive random access memory (ReRAM), phase change memory (PCM), or magnetoresistive random access memory (MRAM).

Resistive memory devices can be formed using memory elements that have two or more stable states with different resistances. Bistable memory has two stable states. A bistable memory element can be placed in a high resistance state or a low resistance state by application of suitable voltages or currents. Voltage pulses are typically used to switch the memory element from one resistance state to the other. Nondestructive read operations can be performed to ascertain the value of a data bit that is stored in a memory cell.

In non-volatile memory structures, selector devices can screen the memory elements from “sneak current” leakage paths that create cross-talk between neighboring cells. The selectors ensure that only the selected cells are read or programmed. Schottky diodes, including p-n junction diodes or metal-semiconductor diodes, can be used as selectors, but their activation process often requires a high thermal budget that may limit the other materials that can be used in the cell, or that may not be acceptable for 3D memory applications. Metal-Insulator-Metal Capacitor (MIMCAP) tunneling diodes may be another option, but to date they have encountered challenges in achieving controllable low barrier height and low series resistance. Ovonic switches and mixed-ionic-electronic conductors (MIECs) have also been explored. Pervasive challenges to various prior approaches include materials that are toxic, scarce, or difficult to work with; insufficient response non-linearity for effective sneak path current suppression; and asymmetric I-V curves incompatible with bipolar switching regimes.

Therefore, advanced memory arrays would benefit from highly non-linear selectors that could be made of materials compatible with the rest of the array and processed at lower temperatures with reliable control of barrier height and series resistance. Preferably, the selectors could optionally be made symmetrical for use in bipolar-switching memory arrays.

### SUMMARY

In some embodiments, a unipolar or bipolar selector device is disclosed that can be suitable for memory device applications. The selector device can have low leakage currents at low voltages to reduce sneak current paths for non-selected devices, and high leakage currents at high voltages to minimize voltage drops during device switching.

In some embodiments, the selector device can include a first electrode, a non-conductive tri-layer, and a second electrode. The non-conductive tri-layer can include a low-bandgap dielectric or semiconductor layer disposed between two higher bandgap dielectric or semiconductor layers. The high-bandgap layers can be doped with a doping material to create defect levels or traps from the conduction band minimum down to an energy level that is offset from the Fermi level of the electrode by an amount less than the write voltage of the memory devices.

In some embodiments, the electrode can include conductive materials having high work function, for example, to minimize the leakage current to the non-conductive tri-layer at low voltages. The electrode materials can have work function greater than about 3 eV, or greater than 4 eV, such as 4.5 or 5 eV. The electrode materials can include TiN, TaN, Pt, Ru, or any mixture or alloy combination thereof.

In some embodiments, the high-bandgap non-conductive layer can include defects or traps, which can allow electrons, which have tunneled through the high-bandgap layer, to pass through the low-bandgap layer. In some embodiments, the high-bandgap layer can be optimized to not significantly affect the current flow at high voltages, and to significantly limit the current flow at low voltages. For example, the high-bandgap layer can include dielectric or semiconductor materials having a leakage current density lower than 10³ A/cm² at a low voltage of 1 V, and having a leakage current density greater than 10⁶ or 10⁷ A/cm² at a high voltage of 2 V.

In some embodiments, the thickness of the high-bandgap non-conductive layer can be less than 20 nm, such as between 5 and 20 nm. In some embodiments, the high-bandgap dielectric layer can include ZrOₓ, HfOₓ, AlOₓ, (x>0) or any mixture or alloy combination thereof.

In some embodiments, the low-bandgap dielectric layer can be optimized to allow high leakage current at high voltages. The low-bandgap layer can include a material or a composition different from that of the high-bandgap dielectric layer. For example, the low-bandgap layer can include dielectric materials having a leakage current density greater than 10⁶ or 10⁷ A/cm² at a high voltage of 2 V.

In some embodiments, the thickness of the low-bandgap dielectric layer can be less than 20 nm, such as between 5 and 20 nm. In some embodiments, the low-bandgap dielectric layer can include TiOₓ, TaOₓ, (x>0) or any mixture or alloy combination thereof.

In some embodiments, the non-conductive tri-layer forms a quantum well. As used herein, a quantum well is an energetic configuration where the energy of the particle (e.g. an electron) is quantized, (i.e. only certain energetic values are allowed inside the well). The bandgap difference between the low-bandgap layer and the surrounding high-bandgap layers may be greater than 0.5 eV and the low-bandgap layer may be 0.5-2 nm thick. For example, the low-bandgap layer may be an oxide of titanium, and the high-bandgap layers may be oxides of aluminum, hafnium or zirconium. The conductivity of the quantum well depends on the applied voltage. At below-threshold voltages, the electrode Fermi level is below the lowest energy level of the quantum well and the tri-layer is non-conductive. At a threshold “turn-on” voltage where the electrode Fermi level matches the lowest energy level of the quantum well, resonant tunneling occurs and the tri-layer becomes conductive.

The quantum well's write voltages are largely determined by the thickness of the low-bandgap layer and the compositions and work functions of the electrodes. The distribution of voltage among the various layers is largely determined by the high-bandgap layer composition and thickness.

In some embodiments, methods to form selector devices, including performing treatments after depositing the electrode layers, the high-bandgap dielectric layers, and/or the low-bandgap dielectric layer are disclosed. The treatment can include rapid thermal annealing or plasma treatment, such as a rapid thermal anneal in temperatures between 200 and 400 C, plasma hydrogen anneal, and/or in-situ annealing after deposition. The treatments can modify the deposited layers to achieve the desired selector characteristics.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a memory array of resistive switching memory elements according to some embodiments.

FIGS. 2A-2B illustrate sneak path currents in a crossbar memory array according to some embodiments.

FIGS. 3A-3B illustrate examples of I-V response for a selector device according to some embodiments.

FIGS. 4A-4B illustrate an example of a current selector together with a memory stack incorporating the current selector according to some embodiments.

FIGS. 5A-5B illustrate examples of band diagrams for selector devices according to some embodiments.

FIGS. 6A-6B illustrates a schematic of the operation of the current selector at low voltages according to some embodiments.

FIGS. 7A-7B illustrates a schematic of the operation of the current selector at high voltages according to some embodiments.

FIGS. 8A-8B illustrates a schematic of the operation of an asymmetrical current selector according to some embodiments.

FIG. 9 illustrates a crossbar memory array according to some embodiments.

FIG. 10 illustrates a flowchart for forming a current selector according to some embodiments.

FIGS. 11A-11C are energy band diagrams for a quantum-well selector.

FIG. 12 is an I-V curve for a symmetric quantum well selector.

FIG. 13 is a sample graph of model results predicting the turn-on voltages of quantum well selectors.

FIG. 14 is a process flowchart for fabricating a quantum-well selector

### DETAILED DESCRIPTION

A detailed description of one or more embodiments is provided below along with accompanying figures. The detailed description is provided in connection with such embodiments, but the scope of coverage is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Crossbar array architecture is promising for various types of non-volatile memory such as phase change memory (PCM) or resistive random access memory (ReRAM) because of the small cell size of 4 F² achievable with each cell at the intersections of perpendicular word lines and bit lines, and the potential to stack multiple layers to achieve very high memory density. Two key challenges for the crossbar architecture are the possibility of current sneak-through paths (e.g., when trying to read a cell in high resistance state adjacent to cells in low resistance state) and the need to avoid changing the resistance of an unselected cell receiving half of the switching voltage applied to the selected cell.

In some embodiments, current selectors or current steering devices are provided with a non-linear current-voltage (I-V) behavior, including low current at low voltages and high current at higher voltages. Unipolar selectors can be appropriate for a unipolar memory, such as PCM, whereas bipolar selector can be more appropriate for a bipolar memory, such as some ReRAM and spin transfer torque random access memory (STT-RAM). The unipolar selector can have high resistance in reverse polarity. The bipolar selector can have high resistance at low voltages. These selectors can prevent sneak-through current even when adjacent memory elements are in low-resistance state. Furthermore, the non-linear I-V response can also provide the current selector with low resistance at higher voltages so that there is no significant voltage drop across the current selector during switching.

In some embodiments, current selectors requiring low temperature processing (e.g., <650 C) are provided, which can be suitable for emerging non-volatile memory architectures such as PCM and STT-RAM. In addition, the current selectors can include fab-friendly materials and can still exhibit a desired device performance.

In some embodiments, electrode/non-conductive tri-layer/electrode stacks are provided as unipolar or bipolar current selectors with low leakage at low voltages and high leakage at high voltages. The non-conductive tri-layer can include two semiconductor or dielectric layers high (i.e., wide) bandgaps.

In some embodiments, the high-bandgap layers also contain defect traps at appropriate energy levels. The energy trap levels are configured such that at low voltages, the carriers from the electrodes cannot access the traps, and thus cannot tunnel through the tri-layer non-conductive stack. This can provide low leakage currents at low voltages. The energy trap levels are also configured such that at high voltages when the device is on, the energy band of the high-bandgap semiconductor or dielectric layers will be bent enough such that the energy levels of the defect traps are now below the electrode Fermi levels. This can allow the carriers to tunnel into the trap levels, and provide high forward leakage current at high voltages.

In some embodiments, defects and/or traps can be introduced into the semiconductor or dielectric layers by making the film non-stoichiometric, or by annealing in a reducing ambient e.g., forming gas or N₂. These defects can also be generated by providing a doping material such as oxygen, carbon, boron, or silicon into the semiconductor or dielectric layers, resulting in, for example, vacancies or interstitials of oxygen, carbon, boron or silicon, which can have energy levels in the bandgap below the conduction band minimum. In some embodiments, the energy levels can be engineered to maintain a proper distance with the conduction band edge, preventing energy levels that are too close or too far from the conduction band edge. In some embodiments, high defect density can be provided to the semiconductor or dielectric layers, e.g., to provide high currents at high voltages until the electron conduction through the semiconductor or dielectric eventually becomes space charge limited conduction.

Since the conduction through the defective high-bandgap layers at high voltages is defect tunneling, the thickness of the high-bandgap layers can be less than 20 nm, such as between 5 and 20 nm, which does not affect the trap tunneling mechanism. The high-bandgap layer can include ZrOₓ, HfOₓ or AlOₓ. The high bandgap can have electron affinity between 1 and 2 eV, and/or can have bandgap energy between 4 and 10 eV.

In some embodiments, a low-bandgap non-conductive layer such as TiOₓ or TaOₓ can be placed in the middle of the two high-bandgap layers. The low-bandgap layer can allow high current densities at higher voltages due to its lower bandgap and/or higher electron affinity. Other layers with low bandgap such as strontium titanate (STO) or ZnO can also be used. The thickness of the low-bandgap layer can be less than 20 nm, such as between 5 and 20 nm. The low-bandgap dielectric can have electron affinity between 3.5 and 4.5 eV, and/or can have bandgap energy between 1 and 3.5 eV.

In some embodiments, a quantum well selector may have doped or undoped high-bandgap layers 5-20 nm thick and a doped or undoped low-bandgap layer 0.5-2.5 nm thick. The bandgap difference between the low-bandgap layer and the high-bandgap layers may be >=0.5 eV. The electrodes are designed to have zero-voltage Fermi levels well below the lowest energy level of the quantum well.

In some embodiments, symmetrical and asymmetrical current selectors can be provided as bipolar and unipolar current steering elements, respectively. For example, in asymmetrical defect-tunneling current selectors, one electrode interface can have a high barrier height (e.g., TiN—ZrO₂ or Pt—TiO₂) and the other electrode interface can be ohmic. In some embodiments of quantum well selectors, an asymmetric response for unipolar switching regimes can be produced by using different materials for the electrodes (or materials with different Fermi levels at zero applied voltage) and (optionally) different materials for the high-bandgap layers, while a symmetric response for bipolar switching regimes can be produced by using the same material for both electrodes (or materials with the same Fermi level at zero applied voltage) and (optionally) the same material for both high-bandgap layers.

The memory cells can be configured in a crossbar memory array. The crossbar memory arrays can include a parallel set of word lines in a first plane that cross an orthogonal set of bit lines in a parallel, but offset, plane. Memory cells can be located at the cross points of the word lines and the bit lines. The memory cells can function as the storage elements of a memory array.

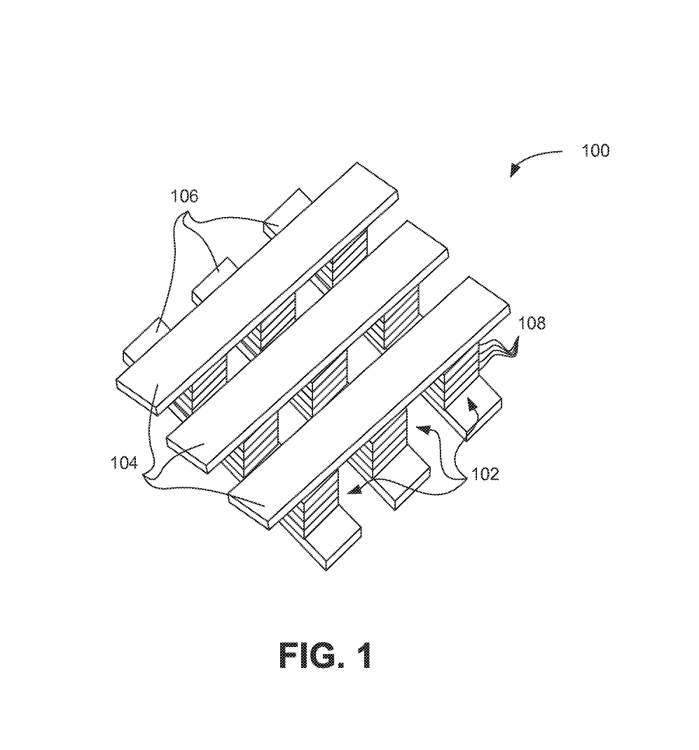

FIG. 1 illustrates a memory array of resistive switching memory elements according to some embodiments. A memory array can include multiple memory devices placed at the cross points of upper and lower conduction lines. Memory array 100 may be part of a memory device or other integrated circuit. Memory array 100 is an example of potential memory configurations; it is understood that several other configurations are possible.

Read and write circuitry may be connected to memory elements 102 using signal lines 104 and crossing signal lines 106, sometimes referred to as word lines and bit lines, to read and write data into the elements 102 of array 100. Individual memory elements 102 or groups of memory elements 102 can be addressed using appropriate sets of signal lines 104 and 106. Each memory element 102 may be formed from one or more layers 108 of materials, as is described in further detail below. In addition, the memory arrays shown can be stacked in a vertical fashion to make multi-layer 3-D memory arrays.

Any suitable read and write circuitry and array layout scheme may be used to construct a non-volatile memory array from individual memory elements such as element 102. For example, horizontal and vertical lines 104 and 106 may be connected directly to the terminals of memory elements 102. The illustration is only one example.

During the operation of the crossbar memory array, such as a read operation, the state of a memory element 102 can be sensed by applying a sensing voltage (i.e., a “read” voltage) to an appropriate set of signal lines 104 and 106. Depending on its history, a memory element that is addressed in this way may be in either a high resistance state or a low resistance state. The resistance of the memory element therefore determines what digital data is being stored by the memory element. If the memory element has a low resistance, for example, the memory element may be said to contain a logic one (i.e., a “1” bit value). If, on the other hand, the memory element has a high resistance, the memory element may be said to contain a logic zero (i.e., a “0” bit value). During a write operation, the state of a memory element can be changed by application of suitable write signals to an appropriate set of signal lines 104 and 106.

Ideally, only the selected memory cell, e.g., during a read operation, experiences a current. However, other currents, often referred as sneak path currents, can flow through unselected memory elements during the read operation. It can be difficult to tell whether a sensed resistance state is really that of a single memory cell. Because all the memory cells in the array are coupled together through many parallel paths, the resistance measured at one cross point can include resistances of the memory cells in other rows and columns in parallel with the resistance of the memory cell at that cross point.

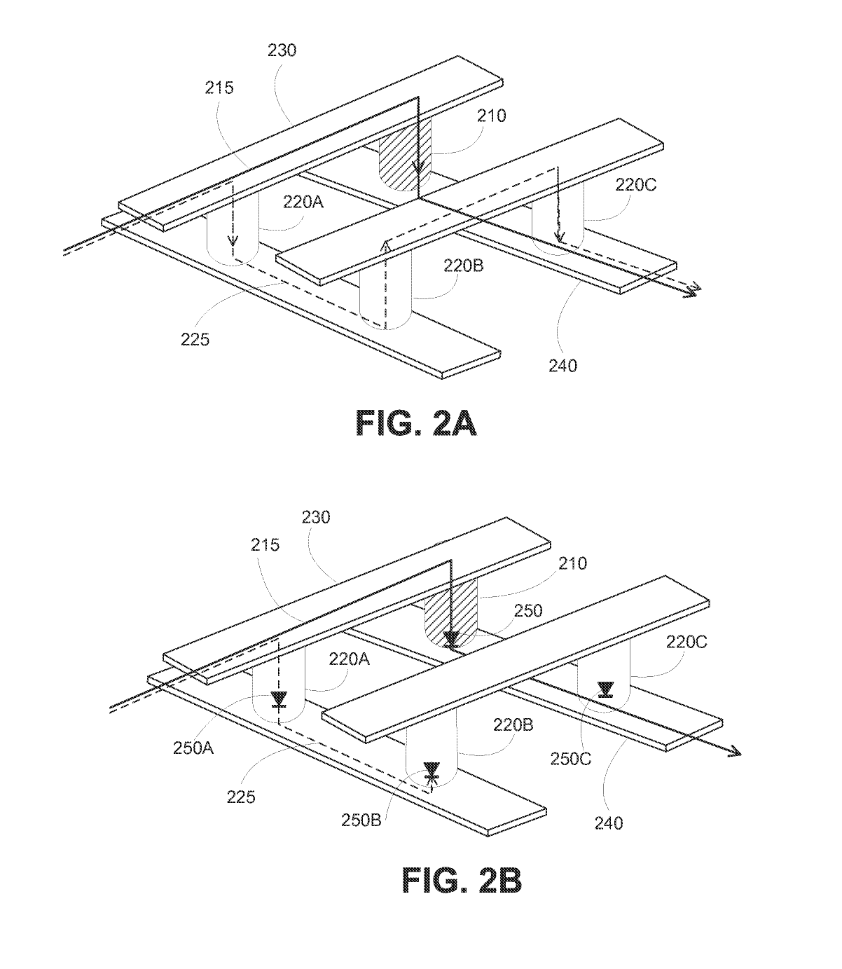

FIGS. 2A-2B illustrates sneak path currents in a crossbar memory array according to some embodiments. Sneak path currents can exist concurrently with operating current when a voltage is applied to the crossbar memory array. In FIG. 2A, a memory cell 210 can be selected; for example, for a read operation, by applying a voltage to signal line 230, and grounding signal line 240. A sensing current 215 can flow through the memory cell 210. However, parallel current paths, e.g., sneak path current, can exist, for example, passing through a series of memory cells 220A, 220B, and 220C. The applied voltage (signal line 230) can generate a current 225 through memory cells 220A-220C. The sneak path current 225 can be particularly large, e.g., larger than the sensing current 215, when the selected cell 210 is in a high resistance state and the neighbor cells 220A-220C are in a low resistance state.

There can be multiple sneak path currents 225. Particularly when the resistances of neighboring memory cells 220A-220C are smaller than that of the selected memory cell 210, the sneak path currents can obscure the sense current 215 through the selected memory cell 210 during a read operation, reducing the accuracy of the reading.

To reduce or eliminate sneak-path currents, a control device, e.g., a selector, can be used in the crossbar memory array. For example, a diode connected in series with each memory cell can isolate the selected memory cell from unselected memory cells by breaking parallel connections among the memory cells. Sneak path current 225 may, at some points, flow in an opposite direction from the sensing current. For example, as seen in FIG. 2A, sneak path current 225 flows upward through memory device 220B, an opposite direction from the downward flow of sensing current 215 through the selected memory cell 210. Thus a one-way electrical device, such as a diode, can be used to block the sneak current path 225.

FIG. 2B shows the array with a diode 250 added to selected cell 210 and diodes 250A-250C attached to neighboring cells 220A-220C. Diodes 250 and 250A-C are configured to allow only downward-flowing currents to pass. Diode 250A allows sensing current 215 to flow downward through selected cell 210, and diode 250A allows sneak path current 225 to flow downward through unselected cell 220A. However, when sneak path current 225 reaches unselected cell 220B and tries to flow upward through it, diode 250B blocks it. Thus sneak path current 225 never reaches unselected 220C, so it cannot or recombine with sensing current 215 to travel down signal line 240.

In some embodiments, methods and systems to reduce current flow through a memory element, for example, during a read operation or a set or reset operation, are provided. The current flow through the memory element can be significantly reduced for voltages lower than write voltages (e.g., read voltages), while still maintaining appropriate current at the write voltages to avoid interfering with the memory device operations. In some embodiments, the current density can be small, e.g., <10³ A/cm², at half of the write voltage (Vₛ/2) to prevent modification to the memory array. The low current at half the write voltage can ensure that when Vₛ/2 is applied to selected cell, e.g., Vₛ/2 is applied to selected row and −Vₛ/2 is applied to selected column, the other cells on the selected row and column are not accidentally programmed or disturbed. The current selector thus should have high resistance at Vₛ/2.

In some embodiments, the current density can be large, e.g., ˜10⁶-10⁷ A/cm², at the write voltage, e.g., set or reset voltage to allow switching of the memory cells. In other words, the current selector can have very low resistance at Vₛ to ensure that the voltage drop across the current selector can be minimal during the memory cell programming.

In some embodiments, methods and systems for a non-linear current response of a memory element are provided. At low voltages, e.g., lower than the write voltages or at half the write voltage, the current can be significantly reduced, while the current can remain the same or can be controlled to ensure proper operation of the memory devices. The lower current values at low voltages can also reduce power consumption and thus improve the power efficiency of the memory arrays.

In some embodiments, selector devices, and methods to fabricate selector devices, for resistive-switching memory elements and crossbar memory array are provided. The selector device can be constructed using familiar and available materials currently used in fabrication facilities. The fabrication process of the selector device may require low thermal budget, suitable for back end or 3D memory applications. In addition, the process can be simple, providing a robust process for manufacturing.

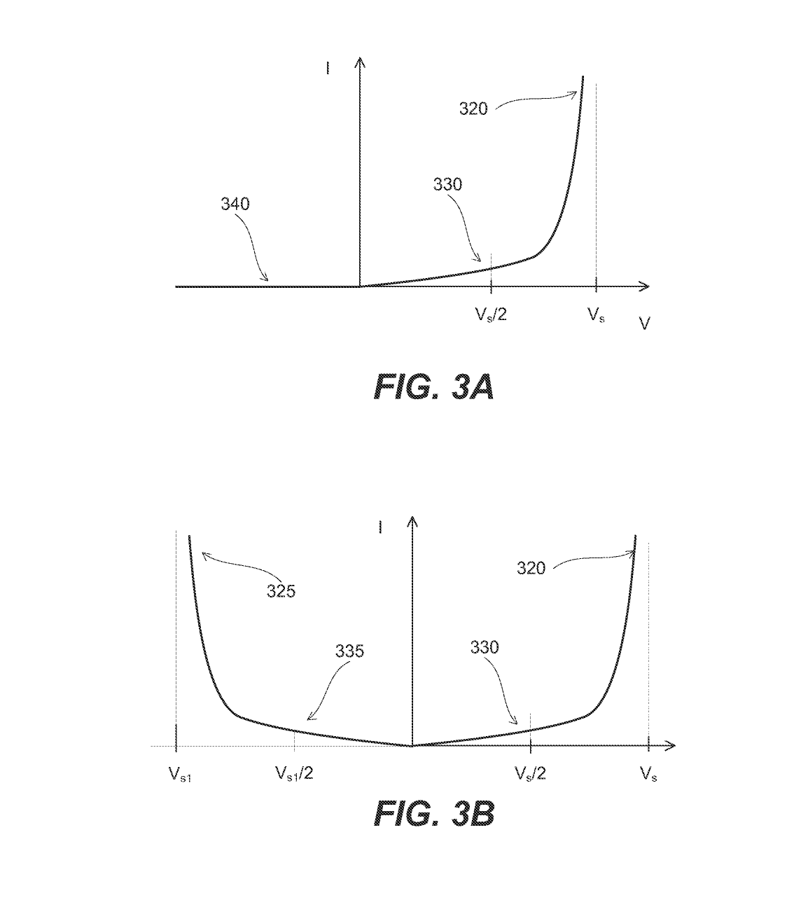

FIGS. 3A-3B illustrate examples of I-V response for a selector device according to some embodiments. The I-V response can be non-linear, including low leakage currents at low voltages and high leakage currents at high voltages. In FIG. 3A, a current voltage response (“I-V”) curve for a selector device for unipolar memory cells is shown. The current can start from low current (e.g., zero current) at zero voltage, and can increase until the write voltage Vₛ, such as the reset voltage Vᵣₑₛₑₜ. The current can slowly increase for low voltages, e.g., less than Vₛ/2, and then rapidly increase toward the write voltage V. The low current at the vicinity of zero voltage can reduce the leakage current. For example, the current density 330 at half the write voltage can be less than about 10³ A/cm² to prevent accidental changes to the memory cells. At high voltages, such as at the write voltage Vₛ, the current can be very high to prevent any interference with the operation of the memory devices. For example, the current density 320 at the write voltage can be higher than about 10⁶ or 10⁷ A/cm² so that the voltage drop across the selector device is small. At the opposite polarity, the current density 340 can be small, e.g., negligible, to be used as a diode for unipolar memory cells.

FIG. 3B shows a current response for a selector device that can be used for bipolar memory cells. The current response curve can be similar in both positive and negative polarities. For example, in the positive voltages, the current can be small 330 at Vₛ/2, and very large 320 at Vₛ. For negative voltages, the current behavior can be similar, e.g., small 335 at half the write voltage Vₛ₁/2, and large 325 at the write voltage Vₛ₁. As shown, both curves are plotted on the upper half of an I-V coordinate, but in general, the left half can be plotted on an (−I)-(V) axis while the right half can be plotted on I-V axis. This approach can account for a linear-log plot, for example, with the voltage axis being linear and the current axis being logarithm.

In some embodiments, the curves can be symmetrical, e.g., Vₛ=Vₛ₁. For example, in a bipolar memory cell, the set voltage Vₛₑₜ and reset voltage Vᵣₑₛₑₜ can have the same magnitude with opposite polarities. In some embodiments, the curves can be asymmetrical, e.g., Vₛ≠Vₛ₁.

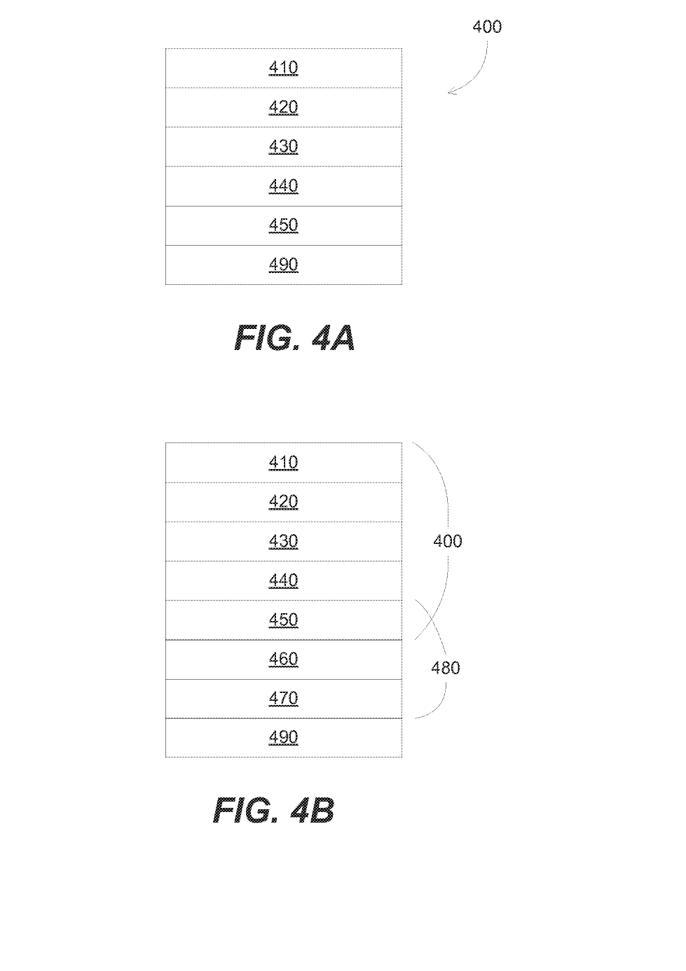

FIGS. 4A-4B illustrate an example of a current selector together with a memory stack incorporating the current selector according to some embodiments. A current selector can include multilayer dielectric or semiconductor disposed between two electrodes. The current selector can be placed adjacent to a memory device to form a memory stack.

In FIG. 4A, a current selector 400 can be disposed on a substrate 490, and can include a first high-bandgap layer 420, a low-bandgap layer 430, and a second high-bandgap layer 440, sandwiched between two electrodes 410 and 450. The first and second high-bandgap layers can be doped with a doping material to create defects at appropriate energy levels, for example, to allow high current at high voltages (such as at the write voltage of the memory devices), and to limit low current at low voltages (such as at half of the write voltage). In some quantum-well embodiments, the low-bandgap layer may be 0.5-2 nm thick and the first and second high-bandgap layers may have bandgaps at least 0.5 eV higher than the bandgap of the low-bandgap layer. The first and second high-bandgap layers can be the same or can be different, e.g., different thicknesses or different materials. The two electrodes can be the same or can be different, e.g., different materials.

In FIG. 4B, a current selector 400 can be placed in series with a memory element 480, which is disposed on a substrate 490. The memory element can include a switching layer 460 sandwiched between two electrodes 450 and 470. As shown, the current selector 400 and the memory element 480 share a common electrode 450, but some embodiments may alternatively have separate electrodes.

In some embodiments, the high-bandgap layers of the current selector 400 can include a dielectric layer or a semiconductor layer, and can function to restrict the current flow across the current selector in the low voltage region, and to allow current flow in the high voltage region. The high-bandgap layers can be doped to form defect traps, which can lower the energy levels of the high-bandgap layers to be below the conduction band minimum levels. The defects can be configured so that the defect energy levels are separated from the Fermi level by an amount equal or less than to the write voltage.

In some embodiments, the high-bandgap defective layer can be formed by introducing defects or traps in a high-bandgap layer, for example, in a HfO₂ layer at energy levels such that carriers can tunnel through the defects in the high-bandgap layer. The choice of film deposition conditions or dopant can be chosen so that defects with desired energy levels can be obtained. For high defect density in the dielectric film, high currents can be achieved at high voltages until the electron conduction through the dielectric eventually becomes space charge limited conduction.

The high-bandgap defective layer can be operated on a defect tunneling principle. At low applied voltages, the band bending is small, and the defect energy levels can still be well above the Fermi level, thus the probability of defect tunneling through the high-bandgap layer is low, resulting in a low current. At high applied voltages, the band bending is higher, bending the defect energy levels to be below the Fermi level, leading to the defect tunneling through the high-bandgap layer, resulting in a high current through the selector device.

In addition, the bandgap and the electron affinity of the high-bandgap layer can be optimized to achieve no tunneling current (or very low tunneling current) at low applied voltages, and significant tunneling current at high applied voltages. For example, dielectric materials having low electron affinity of less than about 3 eV (or less than 3.5 eV in some embodiments), such as 2.7 eV for ZrOₓ, can be used. Dielectric materials having large bandgap of greater than 4 eV (or greater than 4.5 eV in some embodiments), such as 5 eV for ZrOₓ or HfOₓ, or 8 eV for AlOₓ, can be used. The thickness of the high-bandgap layer can be less than 20 nm, such as between 5 and 20 nm. The high-bandgap layer can include ZrOₓ (for example, ZrO₂ doped with a doping material to form defects), HfOₓ (for example, HfO₂ doped with a doping material to form defects), or AlOₓ (for example, Al₂O₃ doped with a doping material to form defects). In some embodiments, the high-bandgap layer can have a leakage current density less than 10³ A/cm² at half the write voltage, e.g., about between 1 and 2 V, and can have a leakage current density of higher than about 10⁶ A/cm², such as higher than 10⁷ A/cm² at the write voltage, e.g., about between 2 and 5 V.

In some embodiments, the low-bandgap layers of the current selector 400 can include a dielectric or semiconductor layer, and can function to enhance the current flow across the current selector, after passing, e.g., defect tunneling, through the high-bandgap layer. The leakage of the low-bandgap layer can be optimized to allow high current flow during the high applied voltages while minimizing the current flow during low applied voltages. In addition, the bandgap and the electron affinity of the low-bandgap layer can be optimized to achieve high current flow during the high applied voltages while minimizing the current flow during low applied voltages. For example, dielectric materials having high electron affinity of greater than about 3 eV (or less than 3.5 eV in some embodiments), such as 4.1 eV for TiO₂, can be used. In some embodiments, the low-bandgap layer can have electron affinity larger than that of the high-bandgap layers. Dielectric materials having low bandgap of less than 3.5 eV (or less than 4 eV in some embodiments), such as 3 eV for TiO₂, 3.2 eV for STO or ZnO can be used. In some embodiments, the low-bandgap layer can have bandgap smaller than that of the high-bandgap layer. The thickness of the low-bandgap layer can be less than 20 nm, such as between 5 and 20 nm. The low-bandgap layer can include TiOₓ, including TiO₂, and TaOₓ, including TaO₂. In some embodiments, the low-bandgap layer can have a leakage current density higher than 10⁶ A/cm², or 10⁷ A/cm² at 2 V. In some embodiments, the low-bandgap layer can have a leakage current higher than that of the high-bandgap layer.

In some quantum-well embodiments, the material and dimensions of the high-bandgap layer may be selected so that the lowest energy level of the quantum well corresponds to a write voltage of the memory array. The material(s) of the electrodes may be selected so that the electrode Fermi level is well below the lowest energy of the quantum well at read voltages or at one-half the write voltage. For example, the electrode materials may include TiN, TaN, Pt, Ru, or any mixture or alloy combination thereof; the high-bandgap layers may include AlOₓ, HfOₓ, or ZrOₓ, and the low-bandgap layer may include TiOₓ.

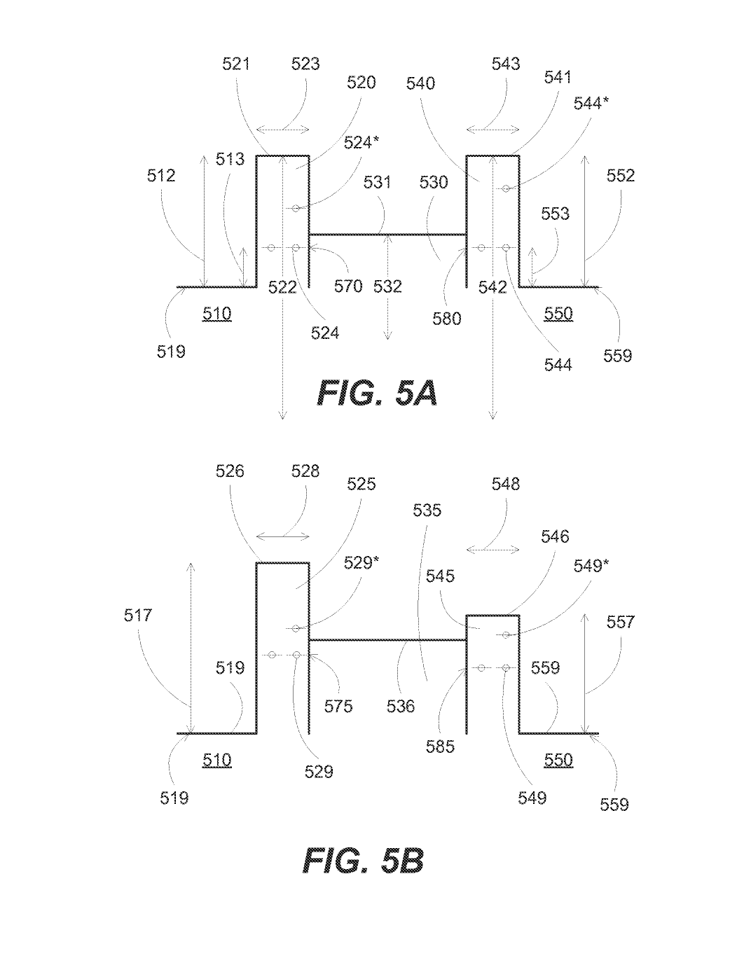

FIGS. 5A-5B illustrate examples of band diagrams for selector devices according to some embodiments. In FIG. 5A, a low-bandgap layer 530 is disposed between two high-bandgap layers 520 and 540. The layers 520, 530, and 540 can be disposed between two electrodes 510 and 550. At equilibrium, e.g., at zero applied voltage, there is no current, or only minimum leakage current due to the energy barrier 513 or 553 between the electrodes and the high-bandgap layers 520 or 540. In some embodiments, the high-bandgap layer 520 or 540 can be characterized as having a leakage current density of less than 10³ A/cm² at half the write voltage. The high-bandgap layer 520 or 540 can have a large bandgap 522 or 542 and a small thickness 523 or 543, respectively. In some embodiments, the low-bandgap layer 530 can be characterized as having a leakage current density of greater than 10⁶ or 10⁷ A/cm² at the write voltage. The low-bandgap layer 530 can have defects or traps 535 to increase it leakage characteristics. The low-bandgap layer 530 can have a low bandgap 532 and a larger thickness than those of the high-bandgap layers 520 and 540.

In some embodiments, the bandgap and electron affinity of the high-bandgap layer 520 or 540 can be chosen to have a high energy barrier 512 or 552 with the Fermi level 519 or 559 of the electrodes. For example, the electrode material and the high-bandgap material can be chosen to form a barrier height of greater than 1 eV, or greater than 2 eV. The high-bandgap layers 520 and 540 can be doped with a doping material to form defects or traps 524/524* and 544/544*. The energy levels of the defects 524/524* and 544/544* can be configured to be near the conduction band minimum 521 and 541. In some embodiments, the defect energy levels are from minimum trap energy levels 570 and 580 to the conduction band minimum 521 and 541. The minimum trap energy levels 570 and 580 can be higher than the Fermi levels 519 and 559 of the electrodes by maximum energy amounts 513 and 553, which are less than write voltage Vₛ of the memory device. In other words, defects are configured so that the write voltage Vₛ is higher than the minimum trap energy levels 570 and 580. In some embodiments, the defect energy levels can be only at the minimum trap energy levels 570 and 580. In some embodiments, the defect energy levels can be distributed from the conduction band minimum 521 and 541 to the minimum trap energy levels 570 and 580.

In some embodiments, the maximum energy amount 513 and 543 can be between 0.3 and 0.7 eV. In other words, the minimum trap energy levels 570 and 580 can be between 0.3 and 0.7 eV from the Fermi level 519 and 559 of the electrodes.

The thickness 523 or 543 of the high-bandgap layer 520 or 540 can be chosen, in conjunction with the electron affinity and bandgap values, to allow defect tunneling at high voltages, e.g., greater than half the write voltage. The selector can have a symmetrical energy band diagram, allowing similar behavior for both polarities of applied voltage, suitable for bipolar memory cells and arrays. Due to the defect tunneling process, the thickness of the high-bandgap layers 520 and 540 can be larger than the normal thickness of a tunnel dielectric layer. For example, the thickness of the layers 520 and 540 can be less than 20 nm, such as between 5 and 20 nm.

In some embodiments, the low-bandgap layer 530 can be characterized as having a leakage current density of greater than 10⁶ or 10⁷ A/cm² at the write voltage. The low-bandgap layer 530 can have optional defects or traps (not shown) to increase its leakage characteristics. The low-bandgap layer 530 can have a low bandgap 532 and a thicker thickness.

In some embodiments, the bandgap and electron affinity of the low-bandgap layer 530 can be chosen to have a low energy barrier with the Fermi level 519 and 559 of the electrodes. For example, the conduction band minimum 531 of the low-bandgap layer 530 can be lower than those of the high-bandgap layers 520 and 540. In some embodiments, the conduction band minimum 531 of the low-bandgap layer 530 can be configured to be at about or higher than the minimum trap energy levels 570 and 580 of the high-bandgap layers 520 and 540. The conduction band minimum 531 can be offset an amount of about less than 0.5 eV or 0.2 eV from the minimum trap energy levels 570 and 580, e.g., the conduction band minimum 531 can be higher to about between 0.5 to 0.9 eV as compared to the Fermi level 519 and 559 of the electrodes 510 and 550.

The thickness of the low-bandgap layer 530 can be chosen, in conjunction with the electron affinity and bandgap values, to allow high leakage current at high voltage region, e.g., greater than half the write voltage. For example, the thickness of the layer 530 can be less than 20 nm, such as between 5 and 20 nm.

The symmetrical selector device can have low leakage current at low voltages, and high current at high voltages. For example, at half the write voltage in either polarity, the leakage current through the selector device can be small. At the write voltage, the current through the selector device can be large.

In FIG. 5B, an asymmetrical selector device is shown. The energy barrier 517 for the left high-bandgap layer 525 can be higher (or lower, not shown) than the energy barrier 557 for the right high-bandgap layer 545. As shown, the conduction band minimum 526 is higher than the conduction band minimum 546. The high-bandgap layers 525 and 545 can be doped to form defects 529/529* and 549/549*, which can have minimum defect energy levels 575 and 585. The minimum defect energy levels 575 and 585 can be about 0.3 to 0.7 eV higher than the Fermi levels 519 and 559 of the electrode 510 and 550. The conduction band minimum 536 of the low-bandgap layer 535 can be about 0.2 eV to 0.3 eV offset, e.g., higher or lower, from the minimum defect energy levels 575 and 585. Thus the conduction band minimum 536 can be about 0.5 eV to 0.9 eV higher than the Fermi level 519 or 559. The thicknesses 528 and 548 of the two high-bandgap layers 525 and 545 can be the same or different.

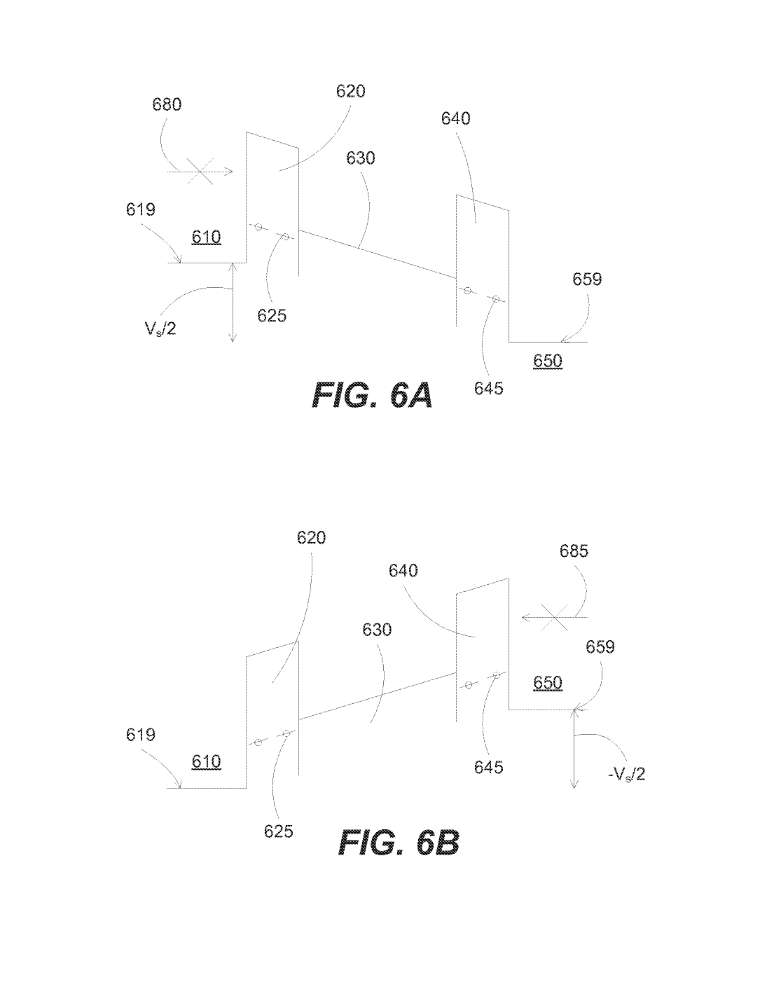

FIGS. 6A-6B illustrates a schematic of the operation of the current selector at low voltages according to some embodiments. The explanation serves as an illustration, and does not mean to bind the disclosure to any particular theory. A current selector can include a first high-bandgap layer 620, a low-bandgap layer 630, and a second high-bandgap layer 640. The current selector can be positioned between electrodes 610 and 650. The energy band shown includes the Fermi levels 619 and 659 for the electrodes, and the electron portion of the band diagram for the current selector. The high-bandgap layers 620 and 640 can include electron defects 625 and 645, e.g., defects that can allow electrons to pass through the high-bandgap layers 620 and 640.

In FIG. 6A, a positive voltage Vₛ/2 can be applied to the electrode 650, lowering the Fermi level 659 of the electrode 650. There is no current 680 (or only minimum leakage current) passing through the current selector in the low voltage region, since the electrons can be blocked by the Schottky barrier and the high-bandgap layer 620. In the low voltage region, the energy levels of the defects 625 are still higher than the Fermi level 619 of the electrode 610, thus there is no significant current flow.

In FIG. 6B, a positive voltage can be applied to the electrode 610, lowering the Fermi level 619 of the electrode 610. Alternatively, a negative voltage −Vₛ/2 can be applied to the electrode 650, raising the Fermi level 659 of the electrode 650. There are no currents 685 passing through the current selector, since the electrons can be blocked by the Schottky barrier and the high-bandgap layer 640. In the low voltage region, the energy levels of the defects 645 are still higher than the Fermi level 659 of the electrode 650, thus there is no significant current flow. Similar behaviors can be seen for hole conduction. The explanation is illustrative. Specific operations of the current selector can depend on the materials, the properties, and the process conditions of the device.

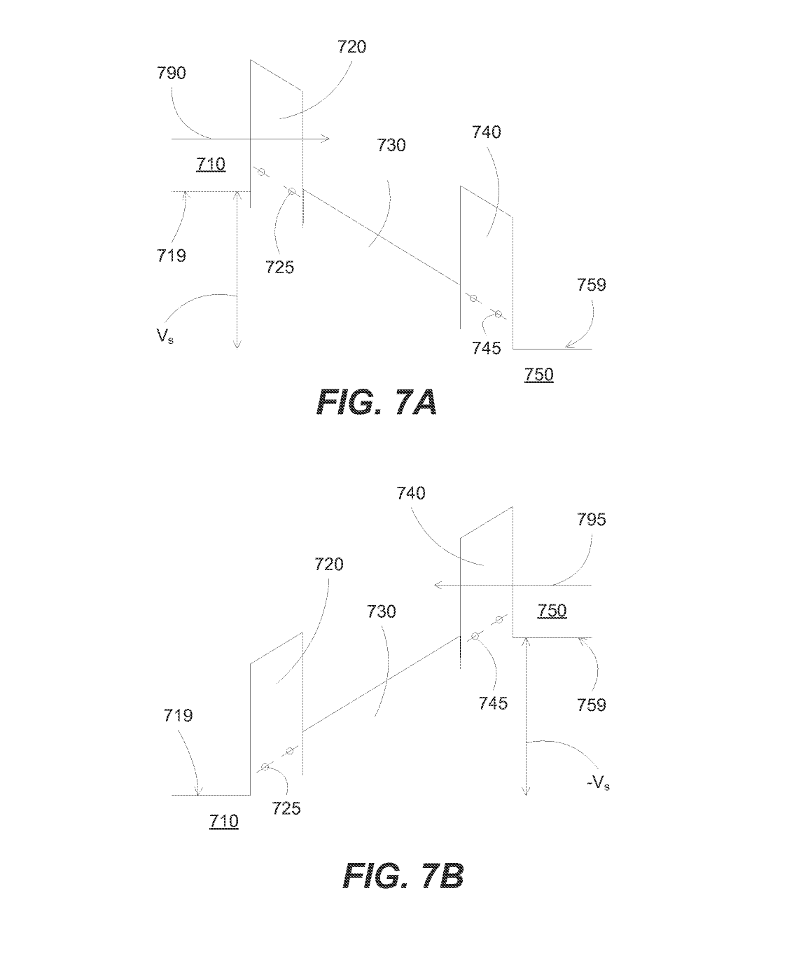

FIGS. 7A-7B illustrates a schematic of the operation of the current selector at high voltages according to some embodiments. A current selector can include a first high-bandgap layer 720, a low-bandgap layer 730, and a second high-bandgap layer 740. The current selector can be positioned between electrodes 710 and 750. The high-bandgap layers 720 and 740 can include electron defects 725 and 745, e.g., defects that can allow electrons to pass through the high-bandgap layers 720 and 740.

In FIG. 7A, a positive voltage Vₛ can be applied to the electrode 750, lowering or raising the Fermi level 759 or 719 of the electrode 750 or 710, respectively. The high applied voltage can generate a defect tunneling current 790 passing through the high bandgap 720. Since the applied voltage Vₛ causes the energy levels of the defects 725 to be bent below the Fermi level 719 of the electrode 710, current 790 can tunnel through defects 725 through the high-bandgap layer 720. Further, since the low-bandgap layer 730 can have a conduction band minimum comparable with the defect energy levels, the current 790 can also pass through the low bandgap 730 to the other electrode 750.

In FIG. 7B, a positive voltage can be applied to the electrode 710, lowering the Fermi level 719 of the electrode 710. Alternatively, a negative voltage −Vₛ can be applied to the electrode 750, raising the Fermi level 759 of the electrode 750. The high applied voltage can generate a tunneling current 795 passing through the high bandgap 740. Since the applied voltage −Vₛ causes the energy levels of the defects 745 to be bent below the Fermi level 759 of the electrode 750, current 795 can tunnel through defects 745 through the high-bandgap layer 740. Further, since the low-bandgap layer 730 can have a conduction band minimum comparable with the defect energy levels, the current 795 can also pass through the low-bandgap 730 to the other electrode 710.

In some embodiments, an asymmetrical device can be provided. The asymmetrical selector device can have low leakage current at low voltages and high current at high voltages in one voltage polarity, and low leakage current at all voltages in an opposite voltage polarity. For example, at half the write voltage in a positive polarity, the leakage current through the selector device can be small. At the write voltage in the same positive polarity, the current through the selector device can be large. At negative bias, the current can be small.

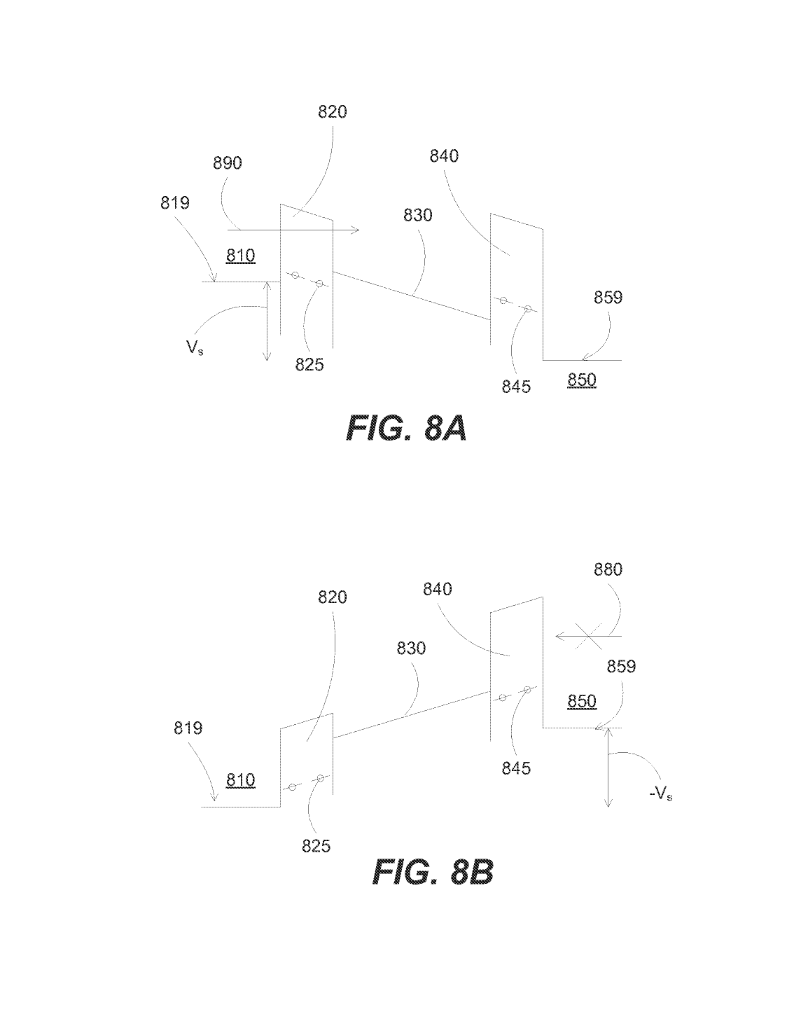

FIGS. 8A-8B illustrates a schematic of the operation of an asymmetrical current selector according to some embodiments. A current selector can include a first high-bandgap layer 820, a low-bandgap layer 830, and a second high-bandgap layer 840. The current selector can be positioned between electrodes 810 and 850. The energy band shown includes the Fermi levels 819 and 859 for the electrodes, and the electron portion of the band diagram for the current selector. The high-bandgap layers 820 and 840 can include electron defects 825 and 845, e.g., defects that can allow electrons to pass through the high-bandgap layers 820 and 840. The high-bandgap layers 820 and 840 can be chosen to present an asymmetrical energy band diagram, for example, by choosing dielectric 840 with larger bandgap, or electrode 850 with lower Fermi level.

In FIG. 8A, a voltage Vₛ can be applied to the electrode 850 or 810, lowering or raising the Fermi level 859 or 819 of the electrode 850 or 810, respectively. The high applied voltage can generate a defect tunneling current 890 passing through the high-bandgap layer 820, due to the high bending of the defect energy levels. Since the low bandgap can have comparable energy level, e.g., the conduction band minimum of the low-bandgap layer 830 is within 0.2 to 0.3 eV of the defect energy levels, the current 890 can also pass through the low-bandgap layer 830.

In FIG. 8B, a voltage with opposite polarity can be applied to the electrode 850 or 810, raising or lowering the Fermi level 859 or 819 of the electrode 850 or 810, respectively. There are no currents 880 passing through the current selector, since the electrons can be blocked by the high energy barrier of the high-bandgap layer 840.

In some embodiments, the memory device including a memory element and a current selector can be used in a memory array, such as a crossbar memory array. For example, the current selector can be fabricated on the memory element, forming a columnar memory device, which can be placed at the cross points of the word lines and bit lines.

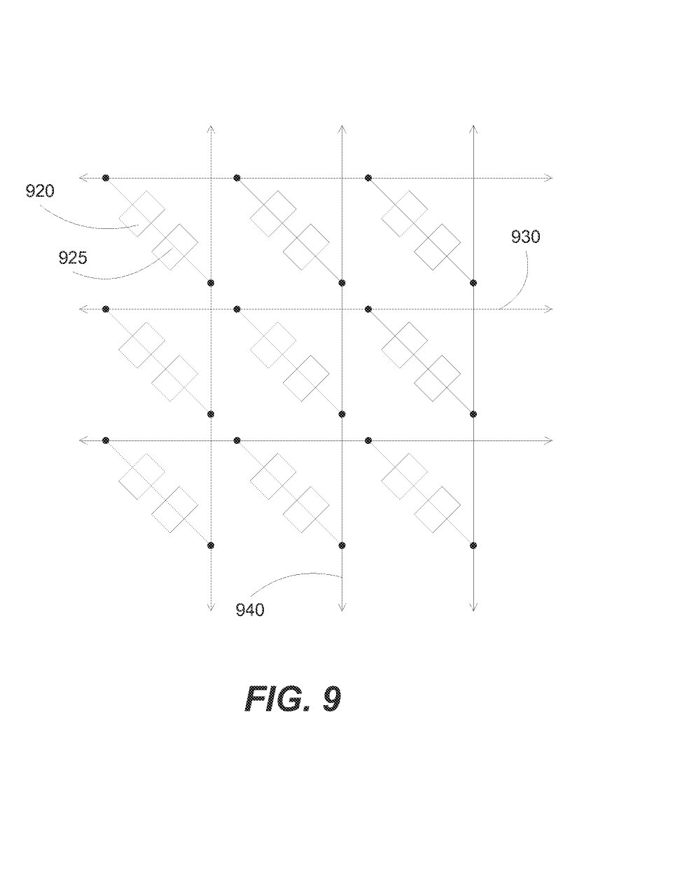

FIG. 9 illustrates a crossbar memory array according to some embodiments. A switching memory device can include a memory element 920 and a current selector 925, which are both disposed between the electrodes 930 and 940. The current selector 925 can be an intervening electrical component, disposed between electrode 930 and memory element 920, or between the electrode 940 and memory element 920. In some embodiments, the current selector 925 may include two or more layers of materials that are configured to provide a non-linear response as discussed above.

In some embodiments, methods to form current selector can be provided. The methods can include depositing a first high-bandgap layer, a low-bandgap layer, and a second high-bandgap layer, together with performing treatments after each layer. The treatment can include rapid thermal annealing or plasma treatment, such as a rapid thermal anneal in temperatures between 200 and 400 C, plasma oxygen anneal, and/or in-situ annealing after deposition. The treatments can passivate or create defects in the high-bandgap layers to achieve the desired defect characteristics.

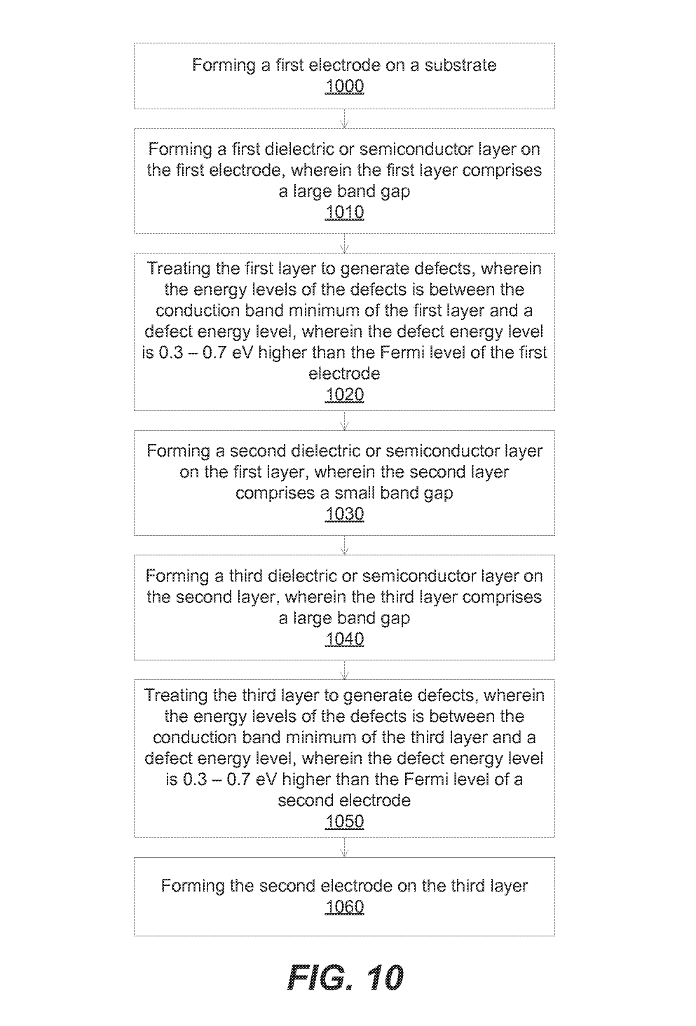

FIG. 10 illustrates a flowchart for forming a current selector according to some embodiments. The described flowchart is a general description of techniques used to form the current selectors described above. The flowchart describes techniques for forming a current selector generally including two electrodes and multiple layers disposed there between. Although certain processing techniques and specifications are described, it is understood that various other techniques and modifications of the techniques described herein may also be used.

In operation 1000, a first electrode layer is formed. The first electrode layer can include TiN, TaN, Pt, or Ru. Other elements can also be used, such as Ti, Al, MoO₂, W, poly-Si, TiSiN, TaSiN, or any combination, mixture or alloy thereof that can be formed using PVD or other processes. The first electrode can have any thickness, for example between about 5 nm and about 500 nm thick.

In operation 1010, a first dielectric or semiconductor layer can be formed on the first electrode. The first dielectric or semiconductor layer can be operable as a high-bandgap layer. The first high-bandgap layer can have low leakage, e.g., less than 10³ A/cm² at 2 V. The first high-bandgap layer can have large bandgap, e.g., in the range of 4-10 eV. The first high-bandgap layer can have low electron affinity, e.g., in the range of 1 to 3.5 eV. The first high-bandgap layer can include ZrOₓ, HfOₓ, or AlOₓ. The thickness of the first high-bandgap layer can be between 5 nm and 20 nm, or can be configured, e.g., incorporating defects or traps, to allow tunneling current at high voltages (2-5 V), and minimizing tunneling at low voltages (less than 2 V).

In operation 1020, a treatment can be performed after depositing the first high-bandgap layer. The treatment can include a plasma treatment or a high temperature treatment. For example, the treatment can include a rapid thermal oxidation at 300 C in oxygen ambient. The treatment can be performed in-situ after the deposition of the first high-bandgap layer. The treatment can include an oxygen radical anneal, e.g., plasma anneal in an oxygen ambient. The treatment can be configured to generate traps or defects, resulting in a high-bandgap defective layer. The treatment can include doping with a doping material, such as oxygen, carbon, boron, or silicon.

In some embodiments, the treatment can be configured to generate defects having energy levels which are about 0.3-0.7 eV higher than the Fermi level of the first electrode. The defects can have energy levels in the vicinity of a minimum defect energy level, which is about 0.3-0.7 eV above the Fermi level of the first electrode. The defects can have energy levels distributed from the minimum defect energy level to the conduction band minimum of the first layer.

In some embodiments, the high-bandgap layer can be deposited by a PVD or ALD process. For example, an ALD process can include O₃ oxidant, at about 250-300 C deposition temperature, using tetrakis (ethylmethylamino) zirconium (TEMAZ), Tris (dimethylamino) cyclopentadienyl Zirconium, tetrakis (ethylmethylamino) hafnium (TEMAHf), tetrakis (dimethylamido) hafnium (TDMAHf) precursors.

In operation 1030, a second dielectric or semiconductor layer can be formed on the first high-bandgap layer. The second dielectric or semiconductor layer can be operable as a low-bandgap layer. The second low-bandgap layer can have high leakage, e.g., in a range of 10⁶ to 10⁷ A/cm² at 2 V. The second low-bandgap layer can have low bandgap, e.g., in the range of 1-3.5 eV. The second low-bandgap layer can high electron affinity, e.g., in the range of 3.5 to 6 eV. The second low-bandgap layer can include TiOₓ, TaOₓ, STO, or ZnO. Other materials can be used, such as TiO₂ or TaO₂. The thickness of the second dielectric layer can be between 5 nm and 20 nm. In some embodiments, the low-bandgap layer can have higher leakage current, smaller bandgap, and/or higher electron affinity than the high-bandgap layer.

An optional treatment can be performed after depositing the second dielectric layer. The treatment can include a plasma treatment or a high temperature treatment. For example, the treatment can include a rapid thermal process at 300 C in a reduced ambient.

In some embodiments, the low-bandgap layer can be deposited by a PVD or ALD process. For example, an ALD process can include _{H2}O oxidant, and at less than about 200 C deposition temperature.

In operation 1040, a third dielectric or semiconductor layer can be formed on the second layer. The third dielectric or semiconductor layer can be operable as a high-bandgap layer. The third high-bandgap layer can include ZrOₓ, HfOₓ, AlOₓ, doped ZrOₓ, doped HfOₓ, or AlOₓ. The thickness of the third dielectric layer can be between 5 nm and 20 nm.

In operation 1050, a treatment can be performed after depositing the third high-bandgap layer. The treatment can include a plasma treatment or a high temperature treatment. For example, the treatment can include a rapid thermal oxidation at 300 C in oxygen ambient. The treatment can include an oxygen radical anneal, e.g., a plasma anneal in an oxygen ambient. The treatment can be configured to generate traps or defects, resulting in a high-bandgap defective layer. The treatment can include doping with a doping material, such as oxygen, carbon, boron, or silicon.

In some embodiments, the treatment can be configured to generate defects having energy levels which are about 0.3-0.7 eV higher than the Fermi level of a second electrode, which is to be deposited after the third layer. The defects can have energy levels in the vicinity of a minimum defect energy level, which is about 0.3-0.7 eV above the Fermi level of the second electrode. The defects can have energy levels distributed from the minimum defect energy level to the conduction band minimum of the third layer.

In operation 1060, a second electrode layer is formed on the current selector stack. The second electrode layer can include TiN, TaN, Ni, Pt, or Ru. Other elements can also be used, such as Ti, Al, MoO₂, W, poly-Si, TiSiN, TaSiN, or any combination, mixture or alloy thereof that can be formed using PVD or other processes. The second electrode can have any thickness, for example between about 5 nm and about 500 nm thick.

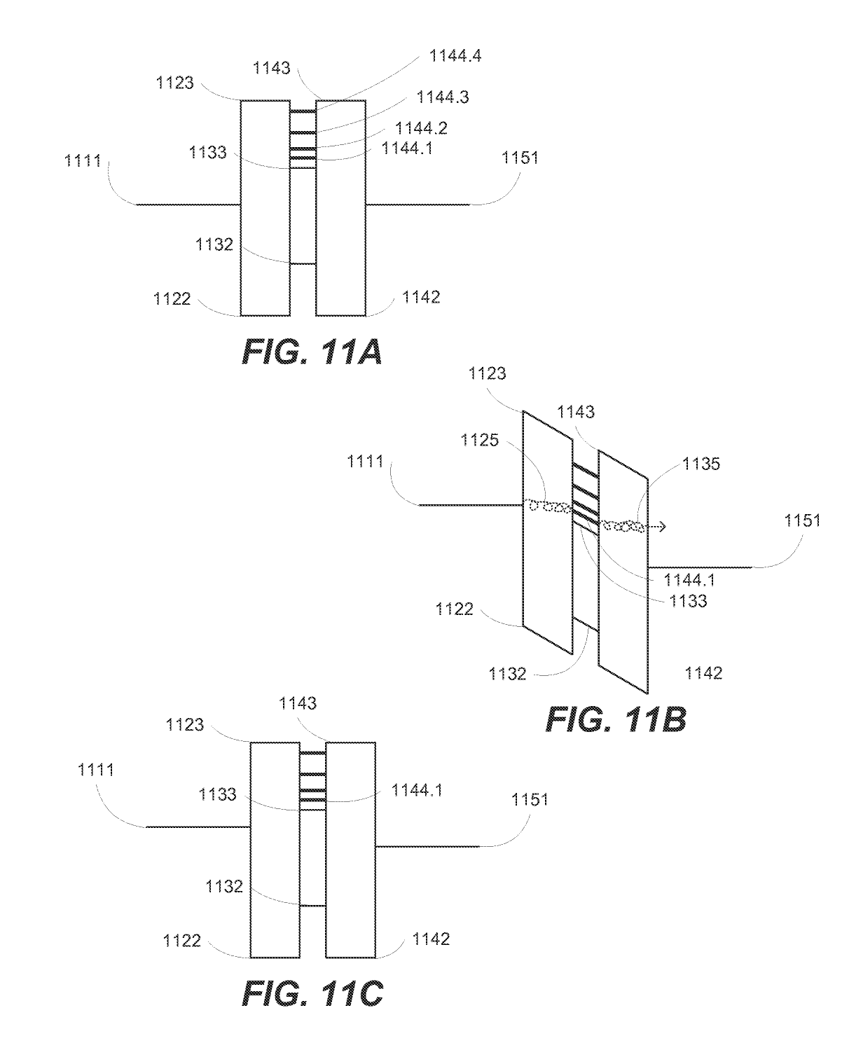

FIGS. 11A-11C are energy band diagrams for a quantum-well selector. FIG. 11A shows the selector energy bands with no voltage applied. The electrodes have Fermi levels 1111 and 1151; their valence and conduction bands coincide. The high-bandgap layers have valence bands 1122 and 1142 and conduction bands 1123 and 1143. The low-bandgap layer in the center has valence band 1132, conduction band 1133, and, because it is thin enough to form a quantum well (e.g., 0.5-2 nm), one or more discrete energy states 1144.1, 1144.2, 1144.3, 1144.4. The quantum well will become conductive if the electrode Fermi levels match any of the different energy states. For example the lowest level 1144.1 may correspond to 1.5V, the next level 1144.2 may correspond to 4V, and the following level 1144.4 may correspond to 10V. In embodiments where no conductivity at all is desired below a threshold voltage, it may be most convenient to work with the lowest of the energy levels, 1141.1.

As long as the Fermi levels 1111, 1151 of both electrodes are below lowest energy level 1141.1, the selector will be in an “off” state, blocking current in either direction, acting like a capacitor. However, as shown in FIG. 11B, at the “turn-on voltage” where Fermi level 1111 reaches the lowest quantum-well energy level 1144.1, the low-bandgap layer suddenly becomes conductive. Electrons can now tunnel through the high-bandgap layers along resonant tunneling paths 1125, 1135; i.e., the entire selector is now conductive, acting like an interconnect.

The illustrated example is symmetric, suitable for bipolar switching; the turn-on voltage Vₜₒ will be the same for both polarities. However, by using electrodes with different Fermi levels (e.g., made of different materials), asymmetric quantum well selectors suitable for unipolar switching can be made. FIG. 11C shows an asymmetric quantum well selector. Fermi level 1111 of one electrode is closer to lowest energy level 1144.1 than Fermi level 1151 of the other electrode. Therefore, the selector will have a lower Vₜₒ for one polarity than for the other polarity.

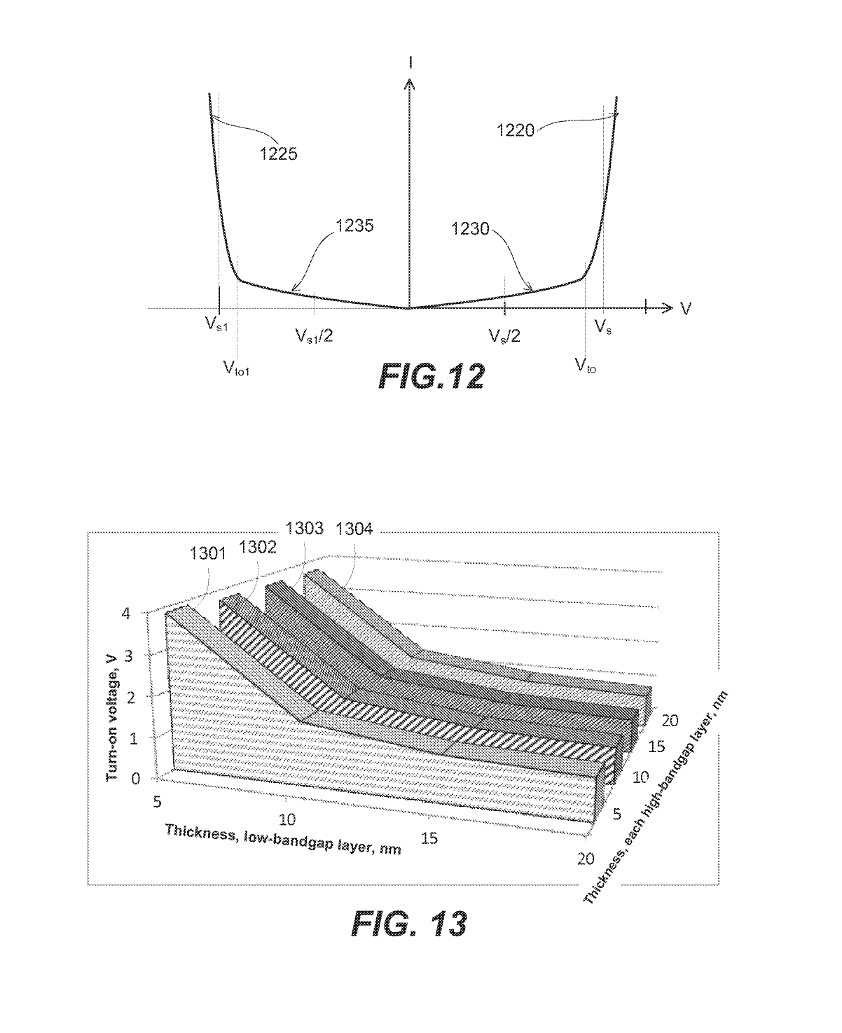

FIG. 12 is an I-V curve for a symmetric quantum well selector. The current response curve can be similar in both positive and negative polarities. For example, in the positive voltages, the current can be small 1230 at V_{s/2}, and very large 1220 at Vₛ. For negative voltages, the current behavior can be similar, e.g., small 1235 at half the write voltage V_{s1/2}, and large 1225 at the write voltage Vₛ₁. The “corners” where shallow I-V slopes 1235, 1230 abruptly become steep I-V slopes 1225, 1220 correspond to the quantum-well turn-on voltages Vₜₒ and Vₜₒ₁. As shown, both curves are plotted on the upper half of an I-V coordinate, but in general, the left half can be plotted on an (−I)-(V) axis while the right half can be plotted on I-V axis. This approach is compatible with a linear-log plot, e.g., with a linear voltage axis and a logarithmic current axis. The illustrated example is not meant to be limiting. For example, in some embodiments the write voltage of the memory cell may be equal to the turn-on voltage of the selector.

Unlike diodes, which pass or block current based on direction of flow, these selectors pass or block current based on the magnitude of voltage applied. As long as Vₛ˜Vₜₒ, V_{s1/2} will be significantly less than Vₜₒ and will be unable to turn the selectors on. Therefore, unselected cells with V_{s1/2} applied will not pass sneak path current because the selectors will act like capacitors and block it.

FIG. 13 is a sample graph of model results predicting the turn-on voltages of quantum well selectors. The electrodes are both titanium nitride with a work function of 4 eV. The high-bandgap layer is alumina with an electron affinity of 1.35 eV and a dielectric constant of 9. The low-bandgap layer is titanium oxide with an electron affinity of 4.2 eV and a dielectric constant of 70. All these materials are commonly used in various types of memory cells, such as ReRAM, and do not require process temperatures as high as some of the diodes in current use. From the marked similarity between curves 1301, 1302, 1303, and 1304 corresponding to different high-bandgap layer thickness, it can be seen that high-bandgap layer thickness does not affect turn-on voltage to first order. Turn-on voltage in these results is most sensitive to low-bandgap layer thickness, with higher sensitivity for smaller thicknesses.

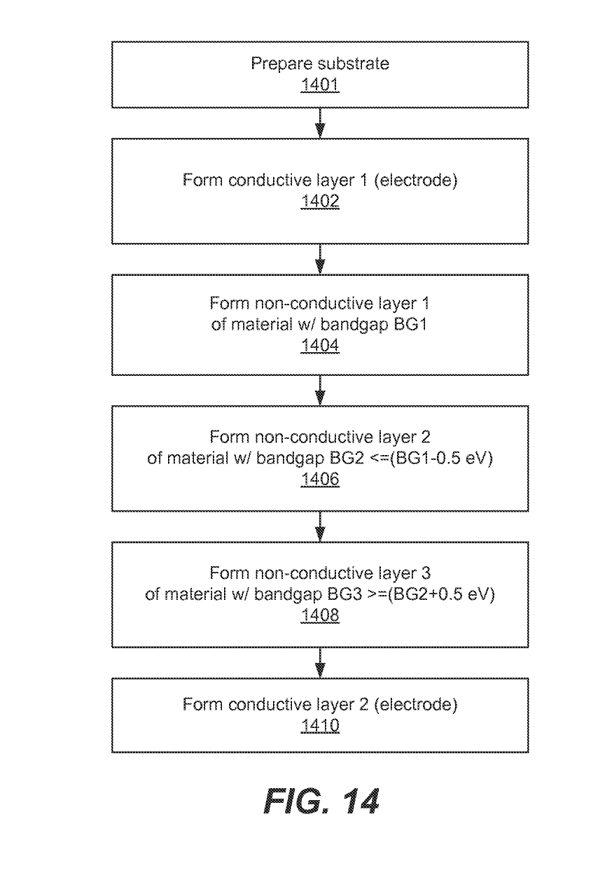

FIG. 14 is a process flowchart for fabricating a quantum-well selector. Step 1401 of preparing the substrate may include cleaning, degassing, other treatments, or forming underlying structures such as signal lines, other interconnect layers, or other device layers. Step 1402 of forming a first conductive layer operable as an electrode may include any of the methods, equipment, or materials discussed with reference to FIG. 10 for forming 5-500 nm thick layers of Pt, Ru, TaN, TiN, or their combinations or alloys. Step 1404 of forming a first non-conductive layer having a first bandgap may include any of the methods, equipment, or materials discussed with reference to FIG. 10 for forming 5-20 nm thick layers of AlOₓ, HfOₓ, ZrOₓ (x>0), or their combinations or alloys. Step 1406 of forming a second non-conductive layer having a second bandgap, lower than the first bandgap by at least 0.5 eV, may include any of the methods, equipment, or materials discussed with reference to FIG. 10 for forming 0.5-2 nm thick layers of TiOₓ (x>0). Step 1408 of forming a third non-conductive layer having a third bandgap, higher than the second bandgap by at least 5 eV, may include any of the methods, equipment, or materials discussed with reference to FIG. 10 for forming 5-20 nm thick layers of AlOₓ, HfOₓ, ZrOₓ (x>0), or their combinations or alloys. Step 1410 of forming a second conductive layer operable as an electrode may include any of the methods, equipment, or materials discussed with reference to FIG. 10 for forming 5-500 nm thick layers of Pt, Ru, TaN, TiN, or their combinations or alloys.

In some embodiments, the first and third layers, and the first and second electrodes, can be the same or can be different. Same materials and processes can produce symmetrical current selectors. Different materials and/or processes can produce asymmetrical current selectors.

In some embodiments, the high-bandgap layers can be different. For example, the first bandgap layer can have a medium bandgap, e.g., larger than the low bandgap of the second layer and smaller than the large bandgap of the third layer.

In some embodiments, the third bandgap layer can have a medium bandgap, e.g., larger than the low bandgap of the second layer and smaller than the large bandgap of the first layer.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A selector, comprising:
a substrate;
a first conductive layer over the substrate, wherein the first layer is operable as a first electrode;
a first non-conductive layer over the first conductive layer;
a second non-conductive layer over the first non-conductive layer;
a third non-conductive layer over the second non-conductive layer; and
a second conductive layer over the third non-conductive layer;
wherein the first non-conductive layer, the second non-conductive layer, and the third non-conductive layer form a quantum well having a lowest energy level;
wherein the first conductive layer has a first Fermi level and the second conductive layer has a second Fermi level;
wherein the first Fermi level and the second Fermi level are less than the lowest energy level when less than a turn-on voltage is applied between the first conductive layer and the second conductive layer; and
wherein one of the first Fermi level or the second Fermi level is equal to the first energy level when a turn-on voltage is applied between the first conductive layer and the second conductive layer.

2. The selector of claim 1, wherein the first conductive layer or the second conductive layer comprises TiN, TaN, Pt, Ru, or an alloy or combination thereof.

3. The selector of claim 1, wherein the first conductive layer or the second conductive layer has a thickness between 5 nm and 500 nm.

4. The selector of claim 1, wherein the first conductive layer and the second conductive layer comprise a same material.

5. The selector of claim 1, wherein the first conductive layer and the second conductive layer comprise different materials from each other.

6. The selector of claim 1, wherein the first non-conductive layer or the third non-conductive layer comprises at least one of AlOₓ, HfOₓ, ZrOₓ, or combination thereof, wherein x>0.

7. The selector of claim 1, wherein the first non-conductive layer or the third non-conductive layer has a thickness between 5 nm and 20 nm.

8. The selector of claim 1, wherein the first non-conductive layer and the third non-conductive layer comprise a same material.

9. The selector of claim 1, wherein the first non-conductive layer and the third non-conductive layer comprise different materials from each other.

10. The selector of claim 1, wherein the second non-conductive layer comprises TiOₓ, wherein x>0.

11. The selector of claim 1, wherein the second non-conductive layer has a thickness between 0.5 nm and 2 nm.

12. The selector of claim 1, wherein the first non-conductive layer has a first bandgap, the second non-conductive layer has a second bandgap, and the third non-conductive layer has a third bandgap; and
wherein the second bandgap is at least 0.5 eV lower than each of the first bandgap and the third bandgap.

13. A memory array, comprising:
a substrate;
a plurality of first signal lines over the substrate;
a plurality of second signal lines over the first signal lines and crossing the first signal lines at a plurality of cross points;
a memory cell comprising a switching stack and a selector between the first and second signal lines at two or more of the cross points;
wherein the selector blocks current at voltages less than a turn-on voltage and conducts current at a turn-on voltage; and
wherein the turn-on voltage causes resonant tunneling through a quantum well in the selector.

14. The memory array of claim 13, wherein the turn-on voltage causes a Fermi level of an electrode of the selector to match an energy level of the quantum well.

15. The memory array of claim 14, wherein the energy level of the quantum well is a lowest energy level of the quantum well.

16. The memory array of claim 13, wherein a write voltage for the switching stack is greater than or equal to the turn-on voltage; and wherein a read voltage for the switching stack is less than the turn-on voltage.

17. The memory array of claim 13, wherein a write voltage for the switching stack is equal to the turn-on voltage.

18. The memory array of claim 13, wherein the switching stack and the selector each use a shared conductive layer as an electrode.

19. The memory array of claim 13, wherein the switching stack is operated by bipolar switching and two conductive layers of the selector have a same Fermi level at zero applied voltage.

20. The memory array of claim 13, wherein the switching stack is operated by unipolar switching and two conductive layers of the selector have different Fermi levels at zero applied voltage.
